(19) United States
(12) Patent Application Publication
(10) Pub. No.: US 2020/0136047 A1
(43) Pub. Date: Apr. 30, 2020

(54) METHOD OF MANUFACTURING AN OLED DISPLAY DEVICE AND OLED DISPLAY DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Jia TANG, Shenzhen, Guangdong (CN); Xiaoxing ZHANG, Shenzhen, Guangdong (CN)

(21) Appl. No.: 15/578,409

(22) PCT Filed: Nov. 16, 2017
(86) PCT No.: PCT/CN2017/111431

§ 371 Date: Nov. 30, 2017

(30) Foreign Application Priority Data
Sep. 28, 2017 (CN) 201710899825.5

(51) Int. Cl. H01L 51/00; H01L 27/32; H01L 51/52; H01L 51/56

(52) U.S. Cl. CPC H01L 51/0018; H01L 27/3246; H01L 51/5218; G03F 7/038; H01L 2227/323; H01L 2251/308; H01L 2251/5315; H01L 51/56

(57) ABSTRACT

A method of manufacture OLED display device and an OLED display device are provided. The method of manufacture OLED display device includes following steps. Forming antireflective layer on anode layer of TFT substrate. Coating negative photoresist material layer on antireflective layer and TFT substrate. Forming pixel defining layer by exposure-and-development process to negative photoresist material layer. Because of the antireflective layer, it could effectively avoids the exposure light be reflected to negative photoresist material corresponding pixel regions by anode and causes photoresist be left on the pixel region when exposure process to the negative photoresist material, by structure of anode is a layer of silver between double indium tin oxide layers. The method of the present invention has no photoresist be left on pixel region such that the OLED emitting layer is uniform thickness and enhances quality of OLED display.

### RELATED APPLICATIONS

The present application is a National Phase of International Application Number PCT/CN2017/111431, filed on Nov. 16, 2017, and claims the priority of China Application No. 201710899825.5, filed on Sep. 28, 2017.

### FIELD OF THE DISCLOSURE

The disclosure relates to a display technical field, and more particularly to a method of manufacture method an OLED display device and a OLED display device.

### BACKGROUND

The Organic Light Emitting Display (OLED) many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device.

The OLED display devices can be classified in two types, which are passive matrix OLED (PMOLED) and active matrix OLED (AMOLED), namely direct addressing and thin-film transistor (TFT) matrix addressing, according to how it is driven. The AMOLED comprises pixels arranged in an array and is a type that actively displays, having high luminous efficiency, and is commonly used in high-definition large-sized display devices.

OLED display usually includes substrate, anode positioned on the substrate, hole inject layer positioned on the anode, hole transport layer positioned on the hole inject layer, emitting layer positioned on the hole transport layer, electron transport layer positioned on the emitting layer, electron inject layer positioned on the electron transport layer, cathode positioned on the electron inject layer. The illuminating principle of OLED is the phenomenon that is the illumination due to the carrier injection and recombination under the electric field driving of organic semiconductor illuminating material and illuminating material. Specifically, the OLED display element generally utilizes the ITO transparent electrode and the metal electrode respectively as the anode and the cathode of the display. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. The latter can illuminate after the radioactive relaxation.

Current OLED display device can be classified in two types, which are Bottom Emission and Top Emission. The light emitted by the emitting layer of top emission OLED display device is passed the cathode of top of the OLED display device. The anode of top emission OLED display device has structure of a layer of silver between double indium tin oxide layers OTO/Ag/ITO), because property of silver, the anode of top emission OLED display device has reflective and also has rough surface. Please refer to FIG. 1 and FIG. 2 are prior art flow chart view of a method of manufacture a top-emission OLED. Firstly, forming an anode 200′ has structure of a layer of silver between double indium tin oxide layers on a substrate element 100′. Forming a negative photoresist material layer 500′ on the anode 200′, and then exposure-and-development process to the negative photoresist material layer 500′ by photo mask 400′. Therefore, forming a pixel defined region 300′ has plurality of openings 310′ for resist pixel regions. When exposure the negative photoresist material layer 500′, the exposure light only emitting to a region outside the to-be—forming openings region 510′ on the negative photoresist material layer 500′. However, the anode 200′ has rough surface and reflectively, the exposure light will be reflective to the to-be—forming openings region 510′ by the anode 200′. And then espousing partial negative photo resist of the to-be—forming openings region 510′ and causes it can't not be removed by development process, so that photoresist will be left in the openings 310′. It effects the uniformity and spreadability of the OLED emitting material in the openings 310′ by stamping process or evaporation process, and cause the OLED display device has dark spot or different mura level which effect display quality.

### SUMMARY

A technical problem to be solved by the disclosure is to provide a method of manufacture an OLED display device, it could produces an OLED display device which is not residues photoresist on the pixel region and the OLED emitting layer is uniform thickness, and enhances display quality.

According to another aspect of the disclosure, the disclosure further provides an OLED display device. There is no photoresist residues on the pixel region for uniform thickness of the OLED emitting layer, and enhances display quality.

The method of manufacture OLED display device comprising following steps.

Step S1, providing TFT substrate, the TFT substrate includes a substrate element and an anode layer positioned on the substrate element.

step S2, forming an antireflective layer on the TFT substrate, and patterning the antireflective layer for forming a plurality of first openings exposing the anode layer.

Step S3, forming a negative photoresist material layer on the TFT substrate and the antireflective layer, and forming a pixel defining layer by exposure-and-development process to the negative photoresist material layer, a plurality of second openings corresponding to the plurality of first openings are pass through and formed on the pixel defining layer, a plurality of pixel regions on the TFT substrate are defined by the plurality of second openings and the plurality of first openings positioned below the plurality of second openings.

Step S4, forming an OLED emitting layer on the plurality of pixel regions of the TFT substrate.

In an embodiment, structure of the anode is a layer of silver between double indium tin oxide layers.

In an embodiment, the antireflective layer is organic photoresist material; specifically step S2 patterning the antireflective layer on the TFT substrate which is exposure-and-development process to the antireflective layer for forming the plurality of first openings on the antireflective layer.

In an embodiment, the antireflective layer is organic shielding material; specifically step S2 pattering the antireflective layer on the TFT substrate which is coating a photoresist layer on the antireflective layer and exposure-and-development process to the photoresist layer, and etching region of the antireflective layer shielded by the developed phtoresist layer for forming the plurality of first openings on the antireflective layer.

In an embodiment, the antireflective layer is absorption material.

In an embodiment, the step S4 forming OLED emitting layer on the plurality of pixel regions of the TFT substrate which is by stamping process or evaporation process.

In an embodiment, the step S4 forming OLED emitting layer on the plurality of pixel regions of the TTFT substrate is by stamping process; the negative photoresist material layer is hydrophobic material.

Furthermore, the disclosure further provides an OLED display device including a TFT substrate, an antireflective layer, a pixel defining layer and an OLED emitting layer. The TFT substrate includes a substrate element and an anode layer positioned on the substrate element. The antireflective layer is positioned on the TFT substrate, and a plurality of first openings exposing the anode layer located on the antireflective layer. The pixel defining layer is positioned on the antireflective layer, and a plurality of second openings are corresponding to the plurality of first openings are pass through and formed on the pixel defining layer, a plurality of pixel regions on the TFT substrate are defined by the plurality of second openings and the plurality of first openings positioned below the plurality of second openings, The OLED emitting layer is positioned on the plurality of pixel regions of TFT substrate. The pixel defining layer is made by negative photoresist material.

In an embodiment, structure of the anode is a layer of silver between double indium tin oxide layers.

In an embodiment, the antireflective layer is shielding material or absorption material.

Furthermore, the disclosure further provides a method of manufacture OLED display device comprising following steps.

Step SI , providing a TFT substrate, the TFT substrate includes a substrate element and an anode layer positioned on the substrate element.

Step S2, forming an antireflective layer on the TFT substrate, and patterning the antireflective layer for forming a plurality of first openings exposing the anode layer.

Step S3, forming a negative photoresist material layer on the TFT substrate and the antireflective layer, and forming a pixel defining layer by exposure-and-development process to the negative photoresist material layer, a plurality of second openings corresponding to the plurality of first openings are pass through and formed on the pixel defining layer, a plurality of pixel regions on the TFT substrate are defined by the plurality of second openings and the plurality of first openings positioned below the plurality of second openings.

Step S4, forming an OLED emitting layer on the plurality of pixel regions of the TFT substrate.

The structure of the anode is a layer of silver between double indium tin oxide layers, and the step S4 forming OLED emitting layer on the plurality of pixel regions of the TFT substrate which is by stamping process or evaporation process.

The method of manufacture the OLED display device of the present invention provides numerous of advantage.

In sum, method of manufacture OLED display device of the present invention, which is forming antireflective layer on the anode of the TFT substrate, and then coating negative photoresist material layer on the TFT substrate and the antireflective layer, and forming a pixel defining layer by exposure-and-development process to the negative photoresist material layer. Because of the antireflective layer , it could effectively avoids the exposure light be reflected to the region of them negative photoresist material corresponding the pixel regions by the anode and causes photoresist be left on the pixel region when exposing the negative photoresist material, by using the anode has structure of a layer of silver between double indium tin oxide layers. Therefore, OLED emitting layer in pixel region has uniform thickness for the following manufacture, and then enhancing quality of OLED display device. The OLED display device of the present invention has no photoresist be left on pixel region such that the OLED emitting layer is uniform thickness and enhances display quality.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 and FIG. 2 are prior art flow chart view of a method of manufacture a top-emission OLED;

FIG. 3 is a flow chart view of a method of manufacture OLED display device according to an embodiment of the disclosure;

FIG. 4 is a schematic view of the step S1 of the method of manufacture OLED display device according to an embodiment of the disclosure;

FIG. 5 is a schematic view of the step S2 of the method of manufacture OLED display device according to an embodiment of the disclosure;

FIGS. 6 to 8 are a schematic view of the step S3 of the method of manufacture OLED display device according to an embodiment of the disclosure; and

FIG. 9 is a schematic view of the step S4 of the method of manufacture OLED display device and structural schematic view of the OLED display device according to an embodiment of the disclosure.

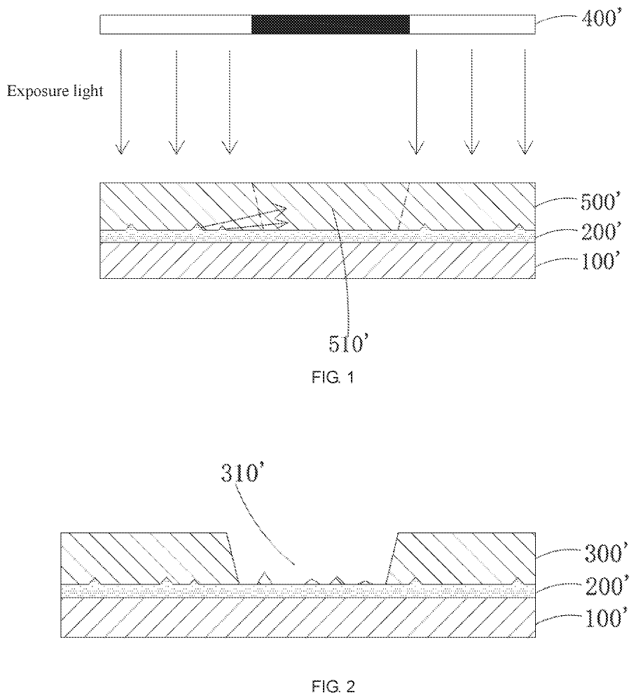

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

The disclosure will be further described in detail with reference to accompanying drawings and preferred embodiments as follows.

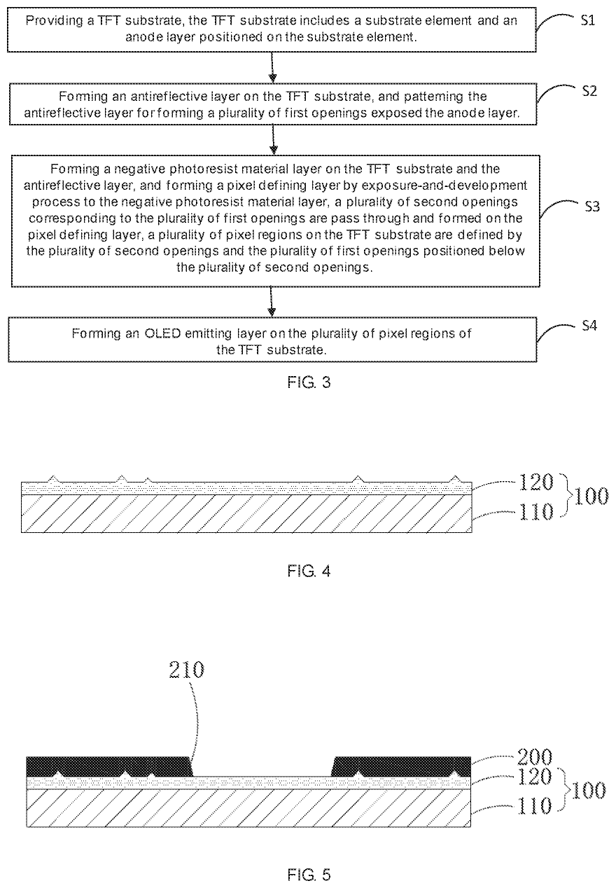

Please refer to FIG. 3, the method of manufacture OLED display device of the present invention comprises following steps.

Step S1, please refer to FIG. 4. Providing a TFT substrate 100.

The TFT substrate 100 includes a substrate element 110 and an anode layer 120 is positioned on the substrate element 110.

Specifically, structure of the anode 120 is a layer of silver between double indium tin oxide layers. It means OLED display device mad by the method of present invention is top-emitting OLED display device.

Specifically, the substrate element 110 is glass material.

Specifically, a TFT array (not shown) is positioned between the substrate element 110 and the anode layer 120. The TFT array includes a plurality of TFT, and the plurality of TFT could be low temperature polysilicon thin film transistor (LTPSTFT), oxide TFT, solid-phase crystallization (SPC) TFT, and others TFT usually used for display field. It is not limited thereto.

Step S2, Please refer to FIG. 5. Forming an antireflective layer 200 on the TFT substrate 100, and patterning the antireflective layer 200 for forming a plurality of first openings 210 exposing the anode layer 120.

Specifically, the antireflective layer 200 could be shielding material, and also could be absorption material which has strong absorption ability to absorb the exposure light during the exposure process.

Further, when the antireflective layer 200 is shielding material, it could be selectively made by an organic resist having high shading rate, which is made for black matrix in prior art. It could also selectively made by inorganic shielding material.

When the antireflective layer 200 is organic photoresist material, specifically embodiment of step S2, patterning the antireflective layer 200, which is exposure-and-development process to the antireflective layer 200 for forming the plurality of first openings 210 on the antireflective layer 200. When the antireflective layer 200 is organic shielding material, specifically embodiment of step S2, patterning the antireflective layer 200, which is coating a photoresist layer on the antireflective layer 200. Exposure-and-development process to the photoresist layer, and etching the region of the antireflective layer 200 shielded by the developed photoresist layer for forming the plurality of first openings 210 on antireflective layer 200.

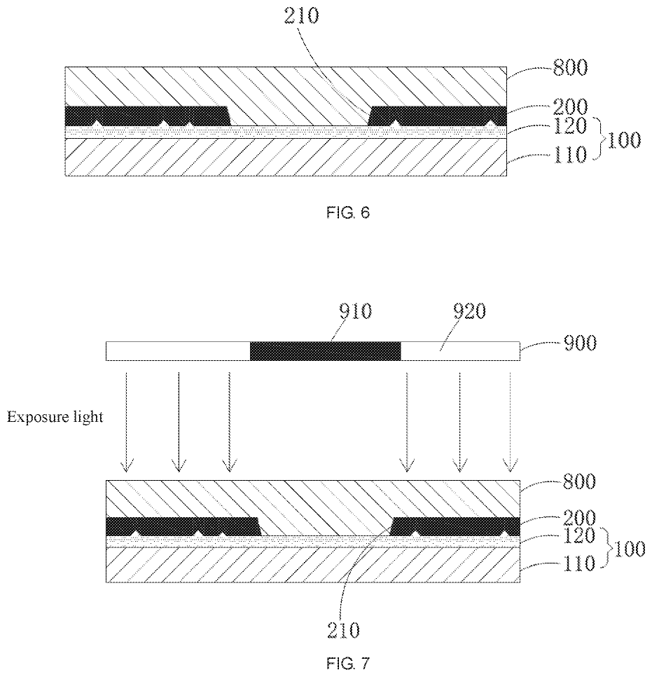

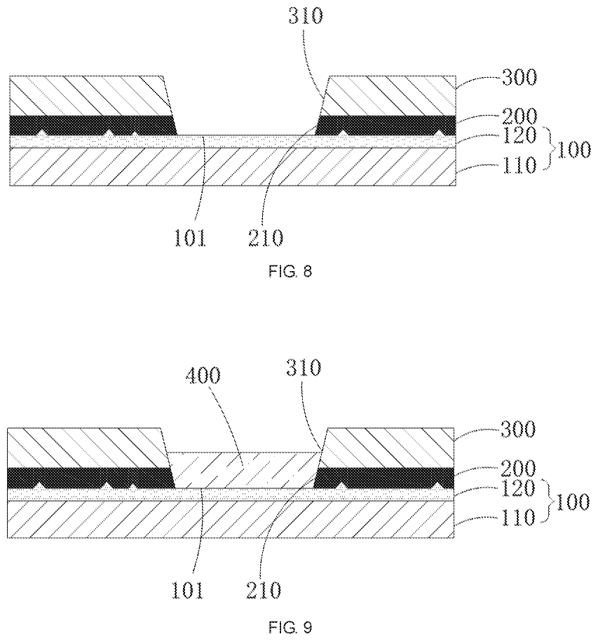

Step S3, Please refer to FIG. 6 to FIG. 8. Forming a negative photoresist material layer 800 on the TFT substrate 100 and the antireflective layer 200, and forming a pixel defining layer 300 by exposure-and-development process to the negative photoresist material layer 800.

A plurality of second openings 310 corresponding to the plurality of first openings 210 are pass through and formed on the pixel defining layer 300, a plurality of pixel regions 101 on the TFT substrate 100 are defined by the plurality of second openings 310 and the plurality of first openings 210 positioned below the plurality of second openings 310.

Specifically, please refer to FIG. 7. In the step S3, Exposing the negative photoresist material layer 800 by photo mask 900. The photo mask 900 has shielding regions 910 for forming the plurality of second openings 310, and transparent regions 920 is the region except for the shielding regions 910. Exposure light pass from the transparent regions 920 to the negative photoresist material layer 800. And then because providing the antireflective layer 200 in the method, even using the anode 120 which has structure of a layer of silver between double indium tin oxide layers, the exposure light would not be reflected to the negative photoresist material layer 800 and the region of shielding region 910 corresponding to photo mask 900 by the anode 120. So that there is no photoresist be left on the pixel region 101 after the development process.

Step S4, Please refer to FIG. 9. Forming OLED emitting layer 400 on the plurality of pixel regions 101 of the TFT substrate 100.

Specifically, the step S4, forming OLED emitting layer 400 on the plurality of pixel regions 101 of the TFT substrate 100, which is by stamping process or evaporation process.

Further, during the step S4, forming OLED emitting layer 400 on the plurality of pixel regions 101 of the TFT substrate 100 by stamping process, the negative photoresist material layer 800 is made by hydrophobic material for avoiding the made material of OLED emitting layer 400 is left on the top of the pixel defining layer 300.

Specifically, because of there is no phtoresist be left on the pixel region 101 after step S3, the step S4 could forming uniform thickness OLED emitting layer 400 in pixel region 101. Therefore, the dark spots or uneven brightness does not happened in OLED display, enhancing quality of display.

Of course, it also have some steps for manufacturing the cathode structure, which as same as prior art, here is not be repeated again.

Please refer to FIG. 9. Based on the same concept of the present invention. The OLED display device made by above method of manufacture is provided in the present invention.

The OLED display device comprises a TFT substrate 100, an antireflective layer 200, a pixel defining layer 300 and an OLED emitting layer 400.

The TFT substrate 100 includes a substrate element 110 and an anode layer 120 positioned on the substrate element 110.

The antireflective layer 200 is positioned on the TFT substrate 100, and a plurality of first openings 210 are exposing the anode layer 120 located on the antireflective layer 200.

The pixel defining layer 300 is positioned on the antireflective layer 200, and a plurality of second openings 310 corresponding to the plurality of first openings 210. The plurality of second openings 310 are pass through and formed on the pixel defining layer 300, a plurality of pixel regions 101 on the TFT substrate 100 are defined by the plurality of second openings 310 and the plurality of first openings 210 which positioned below the plurality of second openings 310.

The OLED emitting layer 400 is positioned on the plurality of pixel regions 101 of the TFT substrate 100.

The pixel defining layer 300 is made by negative photoresist material.

Specifically, structure of the anode 120 is a layer of silver between double indium tin oxide layers. It means OLED display device mad by the manufacture method of present invention is top-emitting OLED display device.

Specifically, the substrate element 110 is glass material.

Specifically, a TFT array (not shown) is positioned between the substrate element 110 and the anode layer 120. The TFT array includes a plurality of TFT, and the plurality of TFT could be low temperature polysilicon thin film transistor (LTPSTFT), oxide TFT, solid-phase crystallization (SPC) TFT, and others TFT usually used for display field. It is not limited thereto.

Specifically, the antireflective layer 200 could be shielding material, and also could be absorption material which has strong absorption ability to absorb the exposure light during the exposure process of manufacture for the pixel defining layer 300.

Further, when the antireflective layer 200 is shielding material, it could be selectively made by an organic resist having high shading rate, which is made for black matrix in prior art. It could also selectively made by inorganic shielding material.

It is notice that, even structure of the anode 120 is a layer of silver between double indium tin oxide layers, because of existing the antireflective layer 200, the exposure light will not be reflected to the region of the negative photoresist material corresponding the pixel regions 101 by the anode 120 cause photoresist left on the pixel region 101, during the exposure process on the negative photoresist material for manufacture the pixel defining layer 300. Therefore, OLED emitting layer 400 in pixel region 101 of the TFT substrate 100 has uniform thickness, and then enhancing quality of OLED display device.

In sum, method of manufacture OLED display device of the present invention, which is forming antireflective layer on the anode of the TFT substrate, and then coating negative photoresist material layer on the TFT substrate and the antireflective layer, and forming a pixel defining layer by exposure-and-development process to the negative photoresist material layer. Because of the antireflective layer, it could effectively avoids the exposure light be reflected to the region of the negative photoresist material corresponding the pixel regions by the anode and causes photoresist be left on the pixel region, during the exposing the negative photoresist material, by using the anode has structure of a layer of silver between double indium tin oxide layers. Therefore, OLED emitting layer in pixel region has uniform thickness for the following manufacture, and then enhancing quality of OLED display device. The OLED display device of the present invention has no photoresist be left on pixel region such that the OLEO emitting layer is uniform thickness and enhances display quality.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A method of manufacture OLED display device, comprising steps of:
step S1, providing a TFT substrate, the TFT substrate includes a substrate element and an anode layer positioned on the substrate element;
step S2, forming an antireflective layer on the TFT substrate, and patterning the antireflective layer for forming a plurality of first openings exposing the anode layer;
step S3, forming a negative photoresist material layer on the TFT substrate and the antireflective layer, and forming a pixel defining layer by exposure-and-development process to the negative photoresist material layer,
wherein a plurality of second openings corresponding to the plurality of first openings are pass through and formed on the pixel defining layer, a plurality of pixel regions on the TFT substrate are defined by the plurality of second openings and the plurality of first openings positioned below the plurality of second openings; and
step S4, forming an OLED emitting layer on the plurality of pixel regions of the TFT substrate.

2. The method of manufacture OLED display device according to claim 1, wherein structure of the anode is a layer of silver between double indium tin oxide layers.

3. The method of manufacture OLED display device according to claim 1, wherein the antireflective layer is organic photoresist material,
wherein specifically step S2 patterning the antireflective layer on the TFT substrate which is exposure-and-development process to the antireflective layer for forming the plurality of first openings on the antireflective layer.

4. The method of manufacture OLED display device according to claim 1, wherein the antireflective layer is organic shielding material;
wherein specifically step S2 pattering the antireflective layer on the TFT substrate which is coating a photoresist layer on the antireflective layer and exposure-and-development process to the photoresist layer, and etching region of the antireflective layer shielded by the developed phtoresist layer for forming the plurality of first openings on the antireflective layer.

5. The method of manufacture OLED display device according to claim 1, wherein the antireflective layer is absorption material.

6. The method of manufacture OLED display device according to claim 1, wherein step S4 forming the OLED emitting layer on the plurality of pixel regions of TFT substrate is by stamping or evaporation.

7. The method of manufacture OLED display device according to claim 6, wherein the step S4 forming the OLED emitting layer on the plurality of pixel regions of TFT substrate which is by stamping process;
wherein the negative photoresist material layer is hydrophobic material.

8. An OLED display device, comprises:
a TFT substrate includes a substrate element and an anode layer positioned on the substrate element;
an antireflective layer positioned on the TFT substrate, and a plurality of first openings exposing the anode layer located on the antireflective layer;
a pixel defining layer positioned on the antireflective layer, and a plurality of second openings are corresponding to the plurality of first openings are pass through and formed on the pixel defining layer, a plurality of pixel regions on the TFT substrate are defined by the plurality of second openings and the plurality of first openings positioned below the plurality of second openings; and
an OLED emitting layer on the plurality of pixel regions of the TFT substrate;
wherein the pixel defining layer is made by negative photoresist material.

9. The OLED display device according to claim 8, wherein structure of the anode is a layer of silver between double indium tin oxide layers.

10. The OLED display device according to claim 8, wherein the antireflective layer is shielding material or absorption material.

11. A method of manufacture OLED display device, comprising steps of:
step S1, providing a TFT substrate, the TFT substrate includes a substrate element and an anode layer positioned on the substrate element;
step S2, forming an antireflective layer on the TFT substrate, and patterning the antireflective layer for forming a plurality of first openings exposing the anode layer;
step S3, forming a negative photoresist material layer on the TFT substrate and the antireflective layer, and forming a pixel defining layer by exposure-and-development process to the negative photoresist material layer,
wherein a plurality of second openings corresponding to the plurality of first openings are pass through and formed on the pixel defining layer, a plurality of pixel regions on the TFT substrate are defined by the plurality of second openings and the plurality of first openings positioned below the plurality of second openings; and
step S4, forming an OLED emitting layer on the plurality of pixel regions of the TFT substrate;
wherein structure of the anode is a layer of silver between double indium tin oxide layers;
wherein step S4 forming the OLED emitting layer on the plurality of pixel regions of TFT substrate which is by stamping process or evaporation process.

12. The method of manufacture OLED display device according to claim 11, wherein the antireflective layer is organic photoresist material;
wherein specifically step S2 patterning the antireflective layer on the TFT substrate which is exposure-and-development process to the antireflective layer for forming the plurality of first openings on the antireflective layer.

13. The method of manufacture OLED display device according to claim 11, wherein the antireflective layer is organic shielding material;
wherein specifically step S2 patterning the antireflective layer on the TFT substrate which is coating a photoresist layer on the antireflective layer and exposure-and-development process to the photoresist layer, and etching region of the antireflective layer shielded by the developed phtoresist layer for forming the plurality of first openings on the antireflective layer.

14. The method of manufacture OLED display device according to claim 11, wherein the antireflective layer is absorption material.

15. The method of manufacture OLED display device according to claim 11, wherein the step S4 forming the OLED emitting layer on the plurality of pixel regions of TFT substrate which is by stamping;
wherein the negative photoresist material layer is hydrophobic material.
